(19) United States
(12) Patent Application Publication
(10) Pub. No.: US 2009/0267056 A1
(43) Pub. Date: Oct. 29, 2009

(54) MEMORY CELL

(75) Inventor: CHIA-CHIEH CHANG, Taipei City (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsin-Chu (TW)

(21) Appl. No.: 12/126,046

(22) Filed: May 23, 2008

(30) Foreign Application Priority Data
Apr. 28, 2008 (TW) 097115514

(51) Int. Cl. H01L 51/05; H01L 29/792

(52) U.S. Cl. 257/40; 257/324; 257/E51.007; 257/E29.309

(57) ABSTRACT

A memory cell comprising a metal-insulator-semiconductor (MIS) structure is disclosed using a homogeneous carrier trapping layer interposed between a semiconductor layer and the gate electrode of a transistor structure so that the operation voltage is reduced and the manufacturing is simplified with lowered cost. The MIS structure comprises: a gate electrode; a semiconductor layer; and a homogeneous carrier trapping layer interposed between the gate electrode and the semiconductor layer; wherein the homogeneous carrier trapping layer comprises novolac.

### BACKGROUND OF THE INVENTION

1. Field of the Invention

The present invention generally relates to a memory cell and, more particularly, to a memory cell using a homogeneous carrier trapping layer interposed between a semiconductor layer and the gate electrode of a transistor structure.

2. Description of the Prior Art

Conventional semiconductor memories such as read-only memories (ROM's) and random access memories (RAM's) are manufactured by complicated semiconductor processing technology with expensive facilities due to the necessary high temperature processing. For ferroelectric ceramic memories, the processing conditions require processing at temperatures in excess of about 600 degrees Celsius. Compared to these expensive inorganic counterparts, organic memories have attracted a great deal of attention because of the remarkable progress in organic electronics and the unique advantages over inorganic memories. For example, organic memories are lightweight and the organic materials are inexpensive and capable of being printed ubiquitously onto plastic substrates.

In order to achieve an ideal organic memory device that is fast, non-volatile and inexpensive, many type of organic memories have been developed. In Adv. Mater. 2006, 18, 3179-3183, Baeg et al. reports an organic non-volatile memory based on pentacene field-effect transistors using a polymeric gate electret. In this paper, a thin layer of poly(α-methylstyrene) (PαMS) interposed between the silicon dioxide gate dielectric layer and the pentacene channel layer is used as a charge storage layer.

In Adv. Mater. 2005, 17, 2692-2695, Naber et al. reports an organic field-effect transistor with programmable polarity. In this paper, poly(vinylidene fluoride/trifluoroethylene) (P(VDF/TrFE)) copolymer is used as the gate dielectric layer. However, such an organic ferroelectric insulator is expensive and the operation voltage of the device using the organic ferroelectric insulator is very high.

Moreover, in U.S. Pat. No. 6,812,509, Xu discloses an organic ferroelectric memory cell. In this patent, ferroelectric polymer such as P(VDF/TrFE) is also used as the gate dielectric layer. Again, such an organic ferroelectric insulator is expensive and the operation voltage of the device using the organic ferroelectric insulator is very high.

In order to overcome the aforementioned problems, there is need in providing a memory cell using a homogeneous carrier trapping layer interposed between a semiconductor layer and the gate electrode of a transistor structure so that the operation voltage is reduced and the manufacturing is simplified with lowered cost.

### SUMMARY OF THE INVENTION

It is one object of the present invention to provide a memory cell using a homogeneous carrier trapping layer interposed between a semiconductor layer and the gate electrode of a transistor structure to achieve simplified manufacturing with lowered cost.

It is another object of the present invention to provide a memory cell using a homogeneous carrier trapping layer interposed between a semiconductor layer and the gate electrode of a transistor structure to achieve reduced operation voltage.

In order to achieve the foregoing object, the present invention provides a memory cell comprising a metal-insulator-semiconductor (MIS) structure, the MIS structure comprising: a gate electrode; a semiconductor layer; and a homogeneous carrier trapping layer interposed between the gate electrode and the semiconductor layer; wherein the homogeneous carrier trapping layer comprises novolac.

It is preferable that the gate electrode comprises a conductive material selected from a group consisting of metal, conductive oxide, conductive polymer and combination thereof.

It is preferable that the semiconductor layer comprises a semiconducting material selected from a group consisting of solid-state semiconductor and organic semiconductor.

It is preferable that the novolac is prepared by a cross-linking reaction in a mixture comprising an organic compound, a cross-linking agent and a solvent.

It is preferable that the organic compound comprises poly-4-vinyl phenol (PVP).

It is preferable that the cross-linking agent comprises organic phenolic monomer capable of performing a condensation reaction.

It is preferable that the cross-linking agent comprises poly melamine-co-formaldehyde (PMF).

It is preferable that the solvent comprises a material selected from a group consisting of ester, ketone, and acetate.

It is preferable that the solvent comprises propylene glycol monomethyl ether acetate (PGMEA).

It is preferable that the novolac is prepared by a cross-linking reaction in a mixture comprising poly-4-vinyl phenol (PVP), poly melamine-co-formaldehyde (PMF) and propylene glycol monomethyl ether acetate (PGMEA).

It is preferable that the ratio of PVP to PMF is 2:1 and the weight percentage of PVP dissolved in PGMEA is smaller than 16%.

It is preferable that the memory cell further comprises a pair of source/drain electrodes electrically coupled to the semiconductor layer.

It is preferable that the pair of source/drain electrodes are disposed on the semiconductor layer.

It is preferable that the pair of source/drain electrodes are embedded in the semiconductor layer.

It is preferable that the pair of source/drain electrodes comprise a conductive material selected from a group consisting of metal, conductive oxide, conductive polymer and combination thereof.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a cross-sectional diagram showing a memory cell in a first embodiment of the present invention;

FIG. 1B is a graph showing the C-V measurement for the memory cell in FIG. 1A;

FIG. 2 is a cross-sectional diagram showing a memory cell in a second embodiment of the present invention; and

FIG. 3 is a cross-sectional diagram showing a memory cell in a third embodiment of the present invention.

### DETAILED DESCRIPTION OF THE PREFERRED EMBODIMENT

The present invention providing a memory cell can be exemplified by the preferred embodiments as described hereinafter.

In the present invention, there is provided a memory cell using a homogeneous carrier trapping layer interposed between a semiconductor layer and the gate electrode of a transistor structure so that a clear hysteresis loop is observed in C-V (capacitance-voltage) measurement of the memory cell. From the viewpoint of memory, the memory cell of the present invention, the operation voltage is reduced and the manufacturing is simplified with lowered cost.

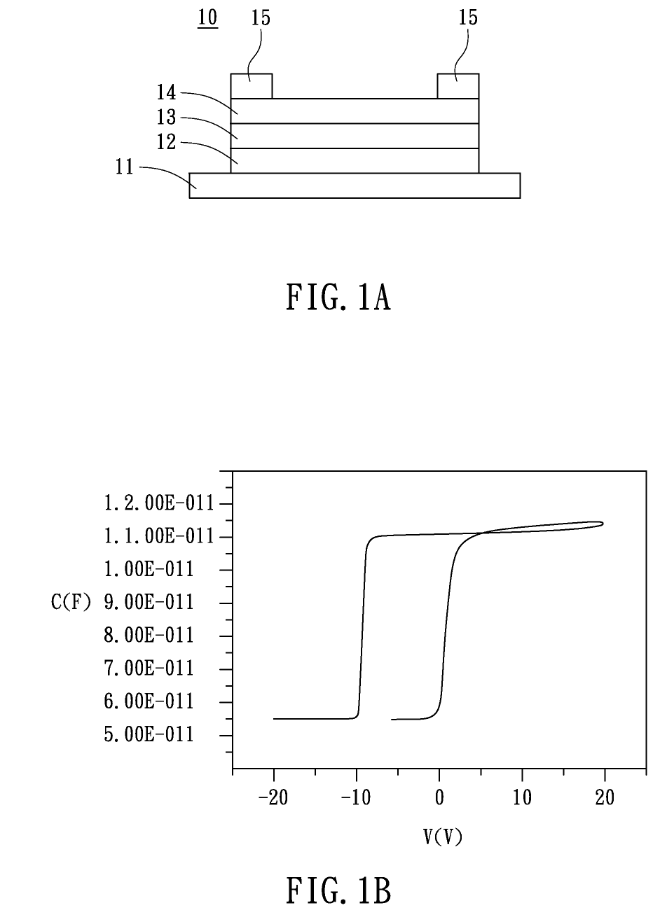

Please refer to FIG. 1A, which is a cross-sectional diagram showing a memory cell in a first embodiment of the present invention. In FIG. 1A, a memory cell 10 uses a field-effect transistor (FET) structure. As all of the individual processing steps are well known in the art, the following description will proceed by focusing on the structure and materials choices for the memory cell and variations in these.

The memory cell 10 is constructed on a substrate 11, which can be either a rigid or flexible substrate. The substrate 11 may comprise a variety of materials having a substantially smooth surface. In the present embodiment, the substrate 11 comprises plastic, semiconductor, metal or glass.

On the upper surface of the substrate 11, a gate electrode 12 is formed. The gate electrode 12 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A homogeneous carrier trapping layer 13 is formed on the upper surface of the gate electrode 12. In the present embodiment, the homogeneous carrier trapping layer 13 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than 16%. The thickness of the homogeneous carrier trapping layer 13 is in the range from approximately 10 nm to approximately 1000 nm.

On the upper surface of the homogeneous carrier trapping layer 13 is formed a semiconductor layer 14. In the present embodiment, the semiconductor layer 14 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the top surface of the semiconductor layer 14, two source/drain electrodes 15 are formed spaced apart with a space therebetween to define a channel region for a field-effect transistor. The source/drain electrodes 15 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

FIG. 1B is a graph showing the C-V measurement for the memory cell in FIG. 1A. In FIG. 1B, a clear C-V hysteresis loop is demonstrated, when the operating voltage varies from −20V to 20V and the capacitance ranges from 50 pF to 1110 pF at 500 kHz. The hysteresis remains unchanged in the scanning direction from positive to negative voltage and vice versa. It is believed that a wide range of hysteresis enables favorable read/write characteristics of the memory cell.

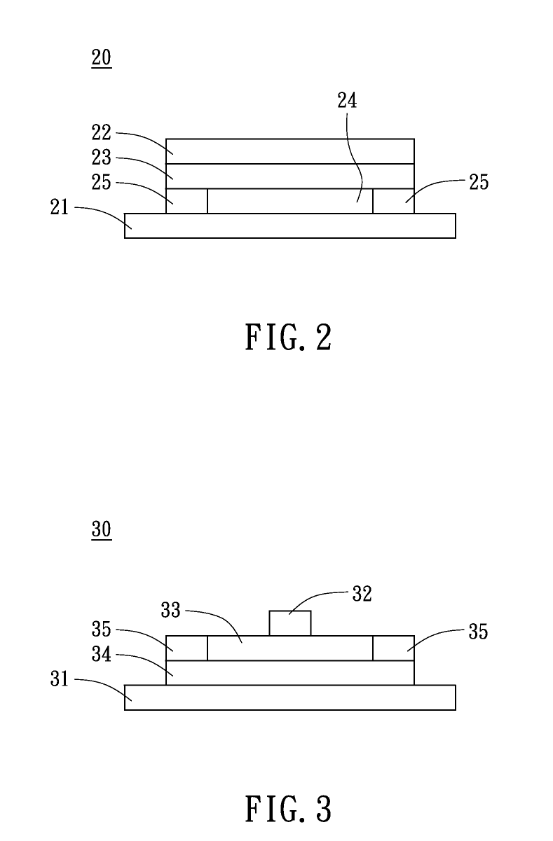

The present invention is exemplified by but not restricted to the first embodiment. For example, FIG. 2 is a cross-sectional diagram showing a memory cell in a second embodiment of the present invention. In FIG. 2, a memory cell 20 uses a field-effect transistor (FET) structure. As all of the individual processing steps are well known in the art, the following description will proceed by focusing on the structure and materials choices for the memory cell and variations in these.

The memory cell 20 is constructed on a substrate 21, which can be either a rigid or flexible substrate. The substrate 21 may comprise a variety of materials having a substantially smooth surface. In the present embodiment, the substrate 21 comprises plastic, semiconductor, metal or glass.

On the upper surface of the substrate 21, two source/drain electrodes 25 are formed spaced apart with a space therebetween to define a channel region for a field-effect transistor. The source/drain electrodes 25 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A semiconductor layer 24 is formed between the two source/drain electrodes 25. In the present embodiment, the semiconductor layer 24 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the upper surface of the semiconductor layer 24, a homogeneous carrier trapping layer 23 is formed. In the present embodiment, the homogeneous carrier trapping layer 23 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than 16%. The thickness of the homogeneous carrier trapping layer 13 is in the range from approximately 10 nm to approximately 1000 nm.

A gate electrode 22 is formed on the upper surface of the homogeneous carrier trapping layer 23. The gate electrode 22 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

The present invention is exemplified by but not restricted to the first and the second embodiments. For example, FIG. 3 is a cross-sectional diagram showing a memory cell in a third embodiment of the present invention. In FIG. 3, a memory cell 30 uses a field-effect transistor (FET) structure. As all of the individual processing steps are well known in the art, the following description will proceed by focusing on the structure and materials choices for the memory cell and variations in these.

The memory cell 30 is constructed on a substrate 31, which can be either a rigid or flexible substrate. The substrate 31 may comprise a variety of materials having a substantially smooth surface. In the present embodiment, the substrate 31 comprises plastic, semiconductor, metal or glass.

On the upper surface of the substrate 31, a semiconductor layer 34 is formed. In the present embodiment, the semiconductor layer 34 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the top surface of the semiconductor layer 34, two source/drain electrodes 35 are formed spaced apart with a space therebetween to define a channel region for a field-effect transistor. The source/drain electrodes 35 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A homogeneous carrier trapping layer 33 is formed between the two source/drain electrodes 35. In the present embodiment, the homogeneous carrier trapping layer 33 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than 16%. The thickness of the homogeneous carrier trapping layer 13 is in the range from approximately 10 nm to approximately 1000 nm.

A gate electrode 32 is formed on the upper surface of the homogeneous carrier trapping layer 33. The gate electrode 32 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

According to the above discussion, it is apparent that the present invention discloses a memory cell using a homogeneous carrier trapping layer interposed between a semiconductor layer and the gate electrode of a transistor structure so that the operation voltage is reduced and the manufacturing is simplified with lowered cost. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A memory cell comprising a metal-insulator-semiconductor (MIS) structure, the MIS structure comprising:
a gate electrode;
a semiconductor layer; and
a homogeneous carrier trapping layer interposed between the gate electrode and the semiconductor layer;
wherein the homogeneous carrier trapping layer comprises novolac and is used in the memory cell so that a clear hysteresis loop is observed in C-V (capacitance-voltage) measurement of the memory cell to exhibit bi-state characteristics.

2. The memory cell as recited in claim 1, wherein the gate electrode comprises a conductive material selected from a group consisting of metal, conductive oxide, conductive polymer and combination thereof.

3. The memory cell as recited in claim 1, wherein the semiconductor layer comprises a semiconducting material selected from a group consisting of solid-state semiconductor and organic semiconductor.

4. The memory cell as recited in claim 1, wherein the novolac is prepared by a cross-linking reaction in a mixture comprising an organic compound, a cross-linking agent and a solvent.

5. The memory cell as recited in claim 4, wherein the organic compound comprises poly-4-vinyl phenol (PVP).

6. The memory cell as recited in claim 4, wherein the cross-linking agent comprises organic phenolic monomer capable of performing a condensation reaction.

7. The memory cell as recited in claim 6, wherein the cross-linking agent comprises poly melamine-co-formaldehyde (PMF).

8. The memory cell as recited in claim 4, wherein the solvent comprises a material selected from a group consisting of ester, ketone, and acetate.

9. The memory cell as recited in claim 8, wherein the solvent comprises propylene glycol monomethyl ether acetate (PGMEA).

10. The memory cell as recited in claim 1, wherein the novolac is prepared by a cross-linking reaction in a mixture comprising poly-4-vinyl phenol (PVP), poly melamine-co-formaldehyde (PMF) and propylene glycol monomethyl ether acetate (PGMEA).

11. The memory cell as recited in claim 10, wherein the ratio of PVP to PMF is 2:1 and the weight percentage of PVP dissolved in PGMEA is smaller than 16%.

12. The memory cell as recited in claim 1, further comprising a pair of source/drain electrodes electrically coupled to the semiconductor layer.

13. The memory cell as recited in claim 12, wherein the pair of source/drain electrodes are disposed on the semiconductor layer.

14. The memory cell as recited in claim 12, wherein the pair of source/drain electrodes are embedded in the semiconductor layer.

15. The memory cell as recited in claim 12, wherein the pair of source/drain electrodes comprise a conductive material selected from a group consisting of metal, conductive oxide, conductive polymer and combination thereof.
